(19) United States
(12) Patent Application Publication
(10) Pub. No.: US 2012/0250231 A1
(43) Pub. Date: Oct. 4, 2012

(54) LOCKING DEVICE AND ELECTRONIC APPARATUS USING THE SAME

(75) Inventors: SHI-XIN XIAO, Shenzhen City (CN); CHUNG-YUAN CHEN, Tu-Cheng (TW); LONG-FONG CHEN, Tu-Cheng (TW); LI CHEN, Shenzhen City (CN)

(73) Assignees: HON HAI PRECISION INDUSTRY CO., LTD., Tu-Cheng (TW); FU TAI HUA INDUSTRY (SHENZHEN) CO., LTD., ShenZhen City (CN)

(21) Appl. No.: 13/165,858

(22) Filed: Jun. 22, 2011

(30) Foreign Application Priority Data
Mar. 29, 2011 (CN) 201110076629.0

(51) Int. Cl. H05K 5/02; F16B 35/04

(52) U.S. Cl. 361/679.01; 411/166

(57) ABSTRACT

A locking device for locking a first component to a second component comprises a fastener and a head. The fastener has an elongated main body, and the head is connected to one end of the main body. The main body inserts into the first component to lock with the second component. The head resists the first component, the head includes a resistance surface facing the main body and at least one restriction structure defined on the resistance surface of the head. The at least one restriction structure engages with the first component, such that the fasteners can be arranged on the first component in a predetermined manner. An electronic apparatus using the locking device is also provided.

### BACKGROUND

1. Technical Field

The present disclosure relates to a locking device for an electronic apparatus.

2. Description of Related Art

Fasteners, such as screws and bolts with Phillips slot heads or straight slot heads, are usually used to lock two components of an electronic apparatus. However, in assembly, it is only demanded that the fasteners are locked tightly, while the arrangement of the heads in the fasteners on the electronic apparatus is not restricted, thus the arrangement of the heads, especially directions of the slots defined in the heads, of the fasteners may be disorganized to influence the appearance of the electronic apparatus.

Therefore, there is room for improvement in the art.

### BRIEF DESCRIPTION OF THE DRAWINGS

The components in the drawings are not necessarily drawn to scale, the emphasis instead being placed upon clearly illustrating the principles of the locking device. Moreover, in the drawings, like reference numerals designate corresponding parts throughout the several views.

FIG. 1 is an exploded view of an electronic apparatus in accordance with an embodiment.

FIG. 2 is a perspective view of the electronic apparatus of FIG. 1.

FIG. 3 is a section view of the electronic apparatus of FIG. 2 taken along III-III line.

### DETAILED DESCRIPTION

Embodiments of the present disclosure will now be described in detail below, with reference to the accompanying drawings.

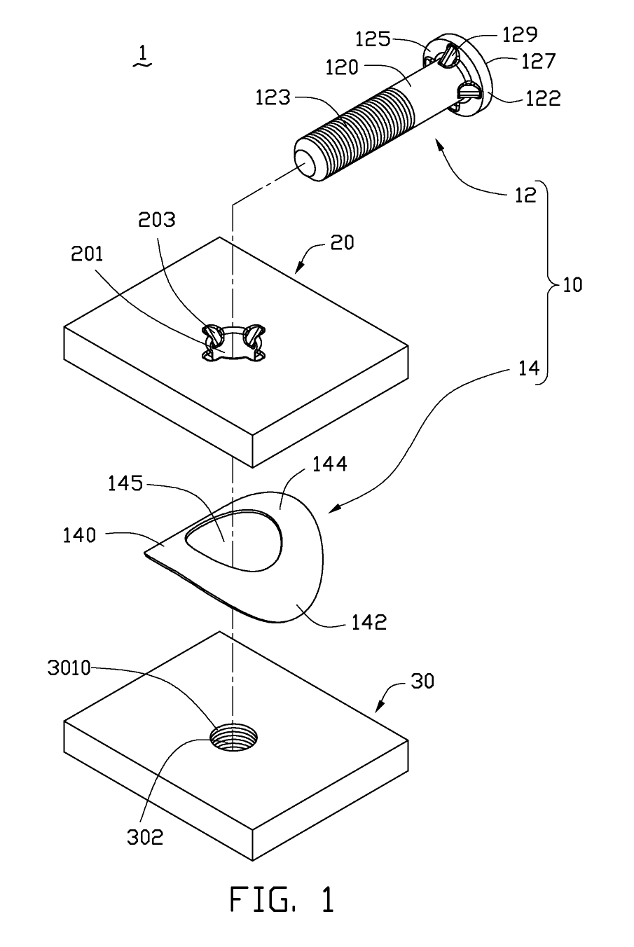

Referring to FIG. 1, an electronic apparatus 1 in accordance with an embodiments includes a locking device 10, a first component 20 and a second component 30. The locking device 10 is used to lock the first component 20 to the second component 30. The electronic apparatus 1 may be a mobile phone, a digital camera, or a computer.

The locking device 10 includes a fastener 12 and an elastic part 14. The fastener 12 includes an elongated main body 120 with threads 123, and a head part 122 connected to one end of the main body 120 away from the threads 123. The main body 120 and the head part 122 may be cylindrical. The diameter of the head part 122 is larger than that of the main body 120. In the embodiment, the diameter of the head part 122 is approximately twice as large as that of the main body 120. One end of the main body 120 away from the head part 122 is shaped as a conical frustum, such that the fastener 12 can be inserted into the first component 20 and the second component 30 conveniently. The elastic part 14 is disposed between the first component 20 and the second component 30, to provide a tension along the axial direction of the main body 120 for the first component 20 and the second component 30.

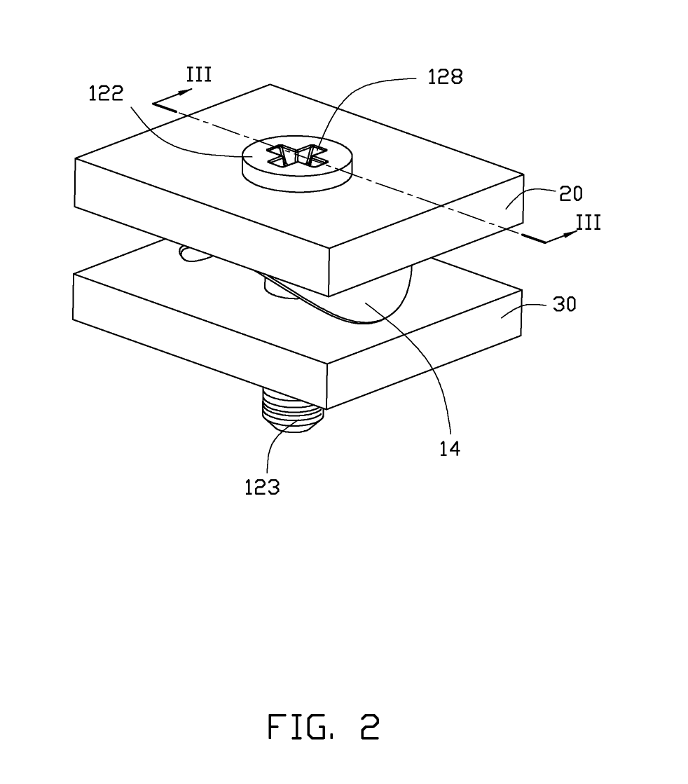

Further referring to FIG. 2, the head part 122 includes a resistance surface 125 surrounding the main body 120 and an operation surface 127 opposite to the resistance surface 125. An operation structure 128 is defined on the operation surface 127, such as a Phillips slot or a standard slot. The operation structure 128 is configured to engage with an operating tool (not shown) for turning the fastener 12. A number of restriction protrusions 129 may be equidistantly defined on the resist surface 125. In the embodiment, equidistantly arranged on the resistance surface 125 there are four protrusions 129. In other embodiments, the number of the protrusion 129 can be more than or less than four.

The elastic part 14 is configured for providing a tension between the first component 20 and the second component 30. The elastic part 14 may be any appropriate resilient members, such as a resilient sheet or a spring. In some embodiments as shown in FIG. 1, the elastic part 14 is a resilient sheet. The elastic part 14 may be made up of an annular bent metal sheet, and include a first end 140, a second end 142 and a connecting part 144 connecting the first end 140 with the second end 142. The first end 140 and the second end 142 respectively extends downwards from opposite ends of the connecting part 144. A through hole 145 is defined in the connecting part 144. The through hole 145 is configured to allow the fastener 12 to pass through the connecting part 144, the connecting part 144 resists against the first component 20, while the first end 140 and the second end 142 resist against the second component 30.

A first opening 201 is defined in the first component 20 for allowing the fastener 12 to pass through the first component 20. The diameter of the first opening 201 is a little more than that of the main body 120 of the fastener 12. Four restriction grooves 203 respectively corresponding to the four protrusions 129 are equidistantly defined on the top surface of the first component 20 and are arranged around the first opening 201.

A second opening 302 is defined in the second component 30 for allowing the fastener 12 to be screwed into. The second opening 302 may be a through hole or a blind hole with threads 3010 defined on the interior wall.

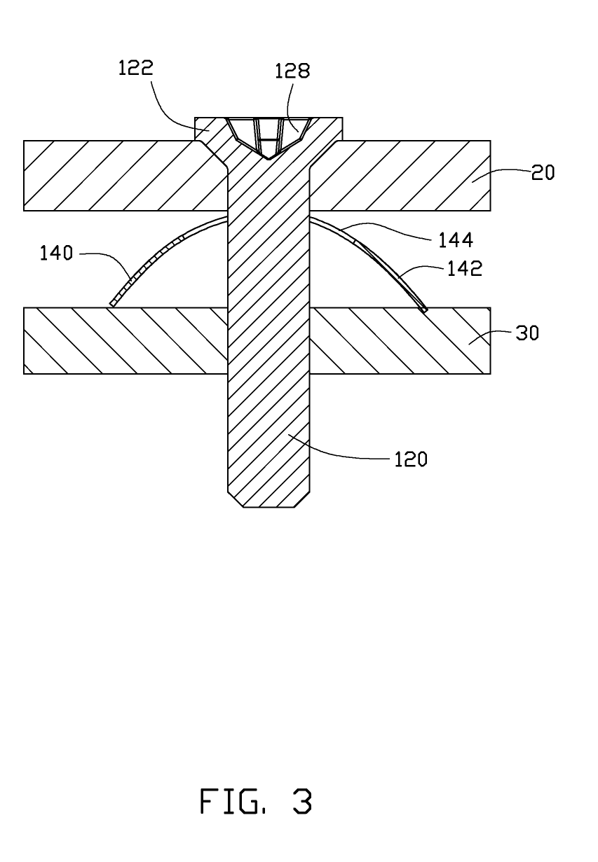

Referring also to FIG. 3, in assembly, the fastener 12 is correspondingly inserted into the first component 20, the elastic part 14, and the second component 30, the operating tool such as a screwdriver is aligned with the operating structure 128 of the fastener 12, and the force is applied clockwise or counter-clockwise by the screwdriver. The fastener 12 is turned by the screwdriver, and the first component 20 is pushed against the elastic part 14 by a user to avoid the first component 20 turning. When the protrusions 129 of the fastener 12 just move into the grooves 203 of the first component 20, the fastener 12 does not entirely lock the first component 20 to the second component 30 firmly, and the grooves 203 stop the protrusions 129. When gradually increasing the force applied to the screwdriver, the elastic part 14 deforms, and the first component 20 moves near to the second component 30. At this moment, the protrusions 129 detach from the groove 203, and the fastener 12 is further screwed with the second component 30 until the first component 20 is locked with the second component 30 firmly.

Because the four protrusions 129 of the fastener 12 and the corresponding four grooves 203 of the first component 20 are provided, the directions of the operating structures 128 of the fasteners 12 relative to the first component 20 can be arranged in a predetermined manner. As such, when there are several fasteners 12 assembled in the electronic apparatus 1, the direction of the operating structure 128 can be arranged in a predetermined manner, to make the electronic apparatus 1 have a more aesthetic appearance

While various embodiments have been described and illustrated, the disclosure is not to be constructed as being limited thereto. Various modifications can be made to the embodiments by those skilled in the art without departing from the true spirit and scope of the disclosure as defined by the appended claims.

What is claimed is:

1. A locking device for locking a first component to a second component comprising:
a fastener having an elongated main body and a head part connected to one end of the main body, the main body being configured to insert into the first component to lock with the second component, the head part being configured to resist on the first component, the head part comprising a resist surface facing the main body; and
at least one restriction structure defined on the resist surface of the head part, the at least one restriction structure being configured to engage with the first component, such that the fasteners can be arranged on the first component in a predetermined manner.

2. The locking device of claim 1, wherein a plurality of restriction structures are defined on the resist surface of the head part, and the restriction structures are equidistantly arranged around the main body.

3. The locking device of claim 2, wherein the plurality of restriction structures comprise a plurality of protrusions radially extending out from the main body.

4. The locking device of claim 3, wherein the first component includes a plurality of grooves corresponding to the plurality of protrusions respectively.

5. The locking device of claim 4, wherein the locking device further includes an elastic part sandwiched between the first component and the second component to provide a tension between the first and second components.

6. The locking device of claim 1, wherein the head part is provided with an operation structure disposed on an operation surface of the head part opposite to the resist surface.

7. An electronic apparatus comprising:
a first component having a first opening;
a second component having a second opening; and
a locking device comprising:
a fastener having a head part, the fastener being passed through the first opening and screwed into the second opening with the head part resisting against the first component; and
at least one restriction structure defined on the head part, the at least one restriction structure being configured to engage with the first component to restrict the arrangement direction of the head part relative to the first component.

8. The electronic apparatus of claim 7, wherein at least another restriction structure is defined on the first component.

9. The electronic apparatus of claim 8, wherein the at least one restriction structure includes a plurality of protrusions, the protrusions are radially defined, the at least another restriction structure includes a plurality of grooves corresponding to the plurality of protrusions.

10. The electronic apparatus of claim 7, wherein the locking device further includes an elastic part sandwiched between the first component and the second component to provide a tension between the first and second components.
